(19) United States
(12) Patent Application Publication
(10) Pub. No.: US 2024/0427317 A1
(43) Pub. Date: Dec. 26, 2024

(54) CONTROL DEVICE, CONTROL METHOD, AND SEMICONDUCTOR MANUFACTURING SYSTEM

(71) Applicant: Tokyo Electron Limited, Tokyo (JP)

(72) Inventors: Ryota AOI, Hokkaido (JP); Kenichi KOBAYASHI, Hokkaido (JP)

(21) Appl. No.: 18/747,506

(22) Filed: Jun. 19, 2024

(30) Foreign Application Priority Data
Jun. 21, 2023 (JP) 2023-101883

(51) Int. Cl. G05B 19/418; H01L 21/67

(52) U.S. Cl. CPC G05B 19/4185; G05B 2219/21099; H01L 21/67005

(57) ABSTRACT

A control device for controlling a semiconductor manufacturing apparatus including a local operation terminal displaying an apparatus screen of the semiconductor manufacturing apparatus and one or more remote operation terminals displaying the apparatus screen, includes: a login state management unit that manages the local operation terminal and at least one of the remote operation terminals that are logged into the same semiconductor manufacturing apparatus; and a communication unit that provides a function of posting and browsing a message between a first user operating the local operation terminal and a second user operating the at least one of the remote operation terminals that are logged into the same semiconductor manufacturing apparatus, by transmitting screen data enabling the posting and browsing of the message to the local operation terminal and the at least one of the remote operation terminals that are logged into the same semiconductor manufacturing apparatus.

### CROSS-REFERENCE TO RELATED APPLICATIONS

This application is based on and claims priority from Japanese Patent Application No. 2023-101883 filed on Jun. 21, 2023, with the Japan Patent Office, the disclosure of which is incorporated herein in its entirety by reference.

### TECHNICAL FIELD

The present disclosure relates to a control device, a control method, and a semiconductor manufacturing system.

### BACKGROUND

A semiconductor manufacturing apparatus is installed in a clean room. Since a constant environment needs to be maintained in a clean room, it is necessary to limit the entry of people as much as possible. A semiconductor manufacturing system has been known where a local operation terminal installed in a clean room and a remote operation terminal installed outside the clean room are connected to a semiconductor manufacturing apparatus installed in the clean room through a network. Each of the local operation terminal and the remote operation terminal simultaneously displays an operation screen of the semiconductor manufacturing apparatus, and receives an operation on the semiconductor manufacturing apparatus from the operation screen (see, for example, Japanese Patent Publication No. 2022-041233).

### SUMMARY

An aspect of the present disclosure provides a control device for controlling a semiconductor manufacturing apparatus including a local operation terminal displaying an apparatus screen of the semiconductor manufacturing apparatus and one or more remote operation terminals displaying the apparatus screen. The control device includes a login state management unit that manages the local operation terminal and at least one of the remote operation terminals that are logged into the same semiconductor manufacturing apparatus; and a communication unit that provides a function of posting and browsing a message between a first user operating the local operation terminal and a second user operating the at least one of the remote operation terminal that are logged into the same semiconductor manufacturing apparatus by transmitting screen data enabling the posting and browsing of the message to the local operation terminal and the at least one of the remote operation terminals that are logged into the same semiconductor manufacturing apparatus.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a configuration diagram of an example of a semiconductor manufacturing system according to an embodiment.

FIG. 2 is a hardware configuration diagram of an example of a computer.

FIG. 3 is a functional block diagram of an example of a control device according to the embodiment.

FIG. 4 is an image diagram of an example of posting and browsing messages according to the embodiment.

FIG. 5 is an image diagram of an example of an apparatus screen displayed on a local operation terminal logged into a semiconductor manufacturing apparatus.

FIG. 6 is an image diagram of an example of a chat screen displayed on the local operation terminal logged into the semiconductor manufacturing apparatus.

FIG. 7 is an image diagram of an example of a chat screen displayed on a remote operation terminal logged into the semiconductor manufacturing apparatus.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of the present disclosure will be described with reference to the drawings.

### <System Configuration>

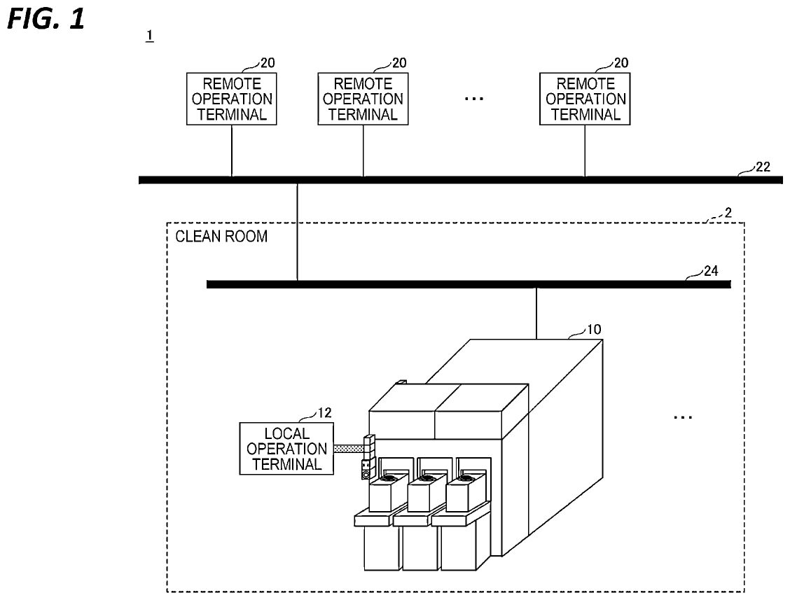

FIG. 1 is a configuration diagram of an example of a semiconductor manufacturing system 1 according to an embodiment. The semiconductor manufacturing system 1 illustrated in FIG. 1 includes a semiconductor manufacturing apparatus 10, a local operation terminal 12, and remote operation terminals 20. The semiconductor manufacturing system 1 is a system that is constructed to remotely control (remote control) the semiconductor manufacturing apparatus 10 from the local operation terminal 12 and one or more remote operation terminals 20.

One or more semiconductor manufacturing apparatuses 10 are installed in a clean room 2. The semiconductor manufacturing apparatuses 10 are communicatively connected through a network 24 such as a local area network (LAN). The semiconductor manufacturing apparatus 10 is an apparatus that performs processing such as film forming, etching, and photolithography.

The semiconductor manufacturing apparatus 10 includes a processing unit that processes a processing target, and a control device that controls the processing unit. Although the control device installed in the semiconductor manufacturing apparatus 10 is not illustrated in FIG. 1, but a state where the local operation terminal 12, which is a display and input device of the control device, is attached to the semiconductor manufacturing apparatus 10, is illustrated as an example.

The remote operation terminals 20 are installed, for example, in an office outside the clean room 2, and are communicatively connected through a network 22 such as a LAN. The network 22 is communicatively connected to a network 24 in the clean room 2. The remote operation terminals 20 installed in an office, may communicate with the control device of the semiconductor manufacturing apparatus 10 through the networks 22 and 24.

The semiconductor manufacturing system 1 in FIG. 1 may display an apparatus screen of the semiconductor manufacturing apparatus 10 on the local operation terminal 12 and the remote operation terminal 20 and control the semiconductor manufacturing apparatus 10 based on a user (operator)'s operation on the apparatus screen. As will be described below, the control device of the semiconductor manufacturing apparatus 10 may accept simultaneous logins (multi-logins) by a plurality of users and display different apparatus screens on the local operation terminal 12 and remote operation terminals 20 that are operated by users logged into the semiconductor manufacturing apparatus 10 (hereinafter, referred to as logged-in local operation terminal 12 and remote operation terminals 20).

Accordingly, the semiconductor manufacturing system 1 in FIG. 1 may independently display different apparatus screens on the local operation terminal 12 and the one or more remote operation terminals 20 that are logged into the control device of the same semiconductor manufacturing apparatus 10, simultaneously, and control the semiconductor manufacturing apparatus 10 from the different apparatus screens. In addition, the control device of the semiconductor manufacturing apparatus 10 controls the display of a chat screen on which messages may be posted and browsed, on the logged-in local operation terminal 12 and one or more remote operation terminals 20, as described later. The chat screen is an example of a function that implements smooth and reliable communication between users operating the local operation terminal 12 and one or more remote operation terminals 20 that are logged into the same semiconductor manufacturing apparatus 10.

In the semiconductor manufacturing system 1 in FIG. 1, users logged into the control device of the same semiconductor manufacturing apparatus 10 from the local operation terminal 12 and the one or more remote operation terminals 20 may browse different apparatus screens and operate the same semiconductor manufacturing apparatus 10 from the different (individual) apparatus screens.

In the semiconductor manufacturing system 1 in FIG. 1, since multiple users operating the local operation terminal 12 and one or more remote operation terminals 20 that are logged into the same semiconductor manufacturing apparatus 10 work simultaneously, the content of an operation performed by one user (for example, a shutdown operation of the semiconductor manufacturing apparatus 10 from the local operation terminal 12 in the clean room 2) may cause another user (user operating the remote operation terminal 20 outside the clean room 2) to be unable to work. Also, since users within the clean room 2 may not bring communication terminals such as smartphones into the clean room 2, there are many cases where the users within the clean room 2 lack any means of contacting users outside the clean room 2.

Therefore, the semiconductor manufacturing system 1 according to this embodiment may display a chat screen on the local operation terminal 12 and one or more remote operation terminals 20 that are logged into the same semiconductor manufacturing apparatus 10, thereby realizing smooth communication between users operating the local operation terminal 12 and one or more remote operation terminals 20 which are logged into the same semiconductor manufacturing apparatus 10.

The local operation terminal 12 is implemented by, for example, a dedicated terminal. The remote operation terminal 20 is realized by, for example, a personal computer (PC), a tablet terminal, a smartphone, or a dedicated terminal.

In addition, the semiconductor manufacturing apparatus 10 may have a control device embedded therein as illustrated in FIG. 1, or a control device may not be necessarily embedded in the semiconductor manufacturing apparatus 10 as long as they are communicatively connected. The control device is a controller with a computer configuration that controls the semiconductor manufacturing apparatus 10. For example, the control device outputs parameters for controlling control components of the semiconductor manufacturing apparatus 10 to the semiconductor manufacturing apparatus 10 according to a recipe.

The control device has a user interface (UI) function that receives an operation on the semiconductor manufacturing apparatus 10 from a user and allows the user to browse information about the semiconductor manufacturing apparatus 10. In addition, the control device has a UI function that allows a user logged into the control device of the same semiconductor manufacturing apparatus 10 to post and browse messages. For example, the UI function of the control device manages the apparatus screen displayed on the local operation terminal 12 and the remote operation terminal 20 as described later.

The semiconductor manufacturing system 1 in FIG. 1 is provided by way of an example, and examples of various system configurations may be provided depending on a use or purpose. For example, the semiconductor manufacturing system 1 may have various configurations, such as a configuration in which control devices of individual semiconductor manufacturing apparatuses 10 are integrated into a control device for a plurality of semiconductor manufacturing apparatuses 10 or a configuration in which the control devices are further divided.

### <Hardware Configuration>

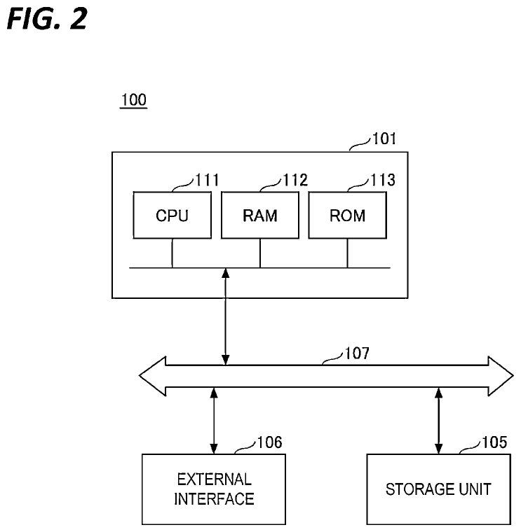

The control device of the semiconductor manufacturing system 1 illustrated in FIG. 1 is implemented, for example, by a computer 100 with a hardware configuration as illustrated in FIG. 2. FIG. 2 is a hardware configuration diagram of an example of the computer 100.

The computer 100 includes a main control unit 101, a storage unit 105, an external interface 106, and a bus 107 that connects the main control unit 101, the storage unit 105, and the external interface 106 to one another. The main control unit 101 includes a central processing unit (CPU) 111, a random access memory (RAM) 112, and a read only memory (ROM) 113. The storage unit 105 is configured to record and read programs or information necessary for control. The storage unit 105 includes a computer-readable storage medium such as a hard disk drive (HDD). The storage medium stores a recipe for a desired processing on a wafer.

In the control device, the CPU 111 executes a program stored in the storage medium of the ROM 113 or the storage unit 105 by using the RAM 112 as a work area, thereby displaying an apparatus screen on the local operation terminal 12 and the remote operation terminals 20 and controlling the semiconductor manufacturing apparatus 10 based on a user's operation on the apparatus screen.

Further, in the control device, the CPU 111 executes a program stored in the storage medium of the ROM 113 or the storage unit 105 by using the RAM 112 as a work area, thereby displaying a chat screen on the local operation terminal 12 and remote operation terminals 20 that are logged into the same semiconductor manufacturing apparatus 10. The control device controls a function of posting and browsing messages between users based on the users' operation on the chat screen.

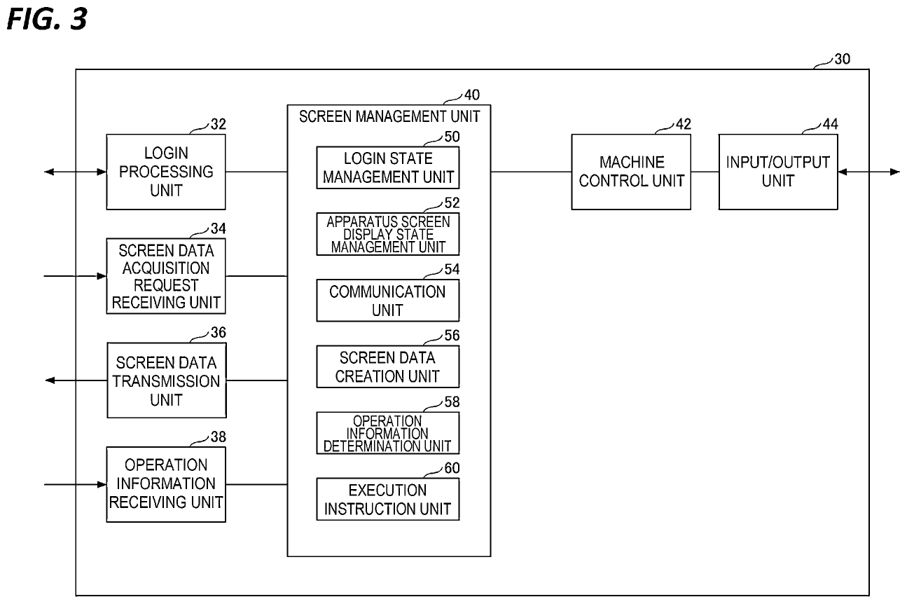

The control device of the semiconductor manufacturing apparatus 10 may implement various functions of FIG. 3 by, for example, executing a program with the hardware configuration of the computer 100 in FIG. 2.

### <Function Configuration>

A control device 30 of the semiconductor manufacturing system 1 according to this embodiment implements, for example, functional blocks of FIG. 3. FIG. 3 is a functional block diagram of an example of a control device according to the embodiment. The functional block diagram of FIG. 3 does not illustrate components that are unnecessary for explanation of the embodiment.

By executing the program, the control device 30 implements a login processing unit 32, a screen data acquisition request receiving unit 34, a screen data transmission unit 36, an operation information receiving unit 38, a screen management unit 40, a machine control unit 42, and an input/output unit 44.

The login processing unit 32 performs a login processing in response to a login request from the local operation terminal 12 and the remote operation terminals 20. The screen data acquisition request receiving unit 34 receives a screen data acquisition request from an application program (hereinafter, simply referred to as an app) installed on the local operation terminal 12 and the remote operation terminals 20. The screen data transmission unit 36 transmits screen data created based on the screen data acquisition request to the local operation terminal 12 and remote operation terminals 20 of a screen data acquisition request source.

The app installed on the local operation terminal 12 and the remote operation terminals 20 displays a screen based on received screen data. The screen displayed based on the received screen data includes an apparatus screen of the semiconductor manufacturing apparatus 10. A user operating the local operation terminal 12 and the remote operation terminals 20 may control the semiconductor manufacturing apparatus 10 by operating the apparatus screen.

The screen displayed based on the received screen data includes a chat screen that provides a function of posting and browsing messages between users operating the local operation terminal 12 and remote operation terminals 20 logged into the same semiconductor manufacturing apparatus 10. The users operating the local operation terminal 12 and the remote operation terminals 20 may perform smooth and reliable communication between the users logged into the same semiconductor manufacturing apparatus 10, by operating the chat screen.

For example, the local operation terminal 12 and the remote operation terminals 20 that display the apparatus screen or the chat screen transmit operation information to the control device 30, based on the user's operation on the apparatus screen or chat screen. Here, the operation information may inform the control device 30 of the user's operation on the apparatus screen or on the chat screen displayed by the local operation terminal 12 and the remote operation terminals 20. The operation information receiving unit 38 of the control device 30 receives operation information transmitted from the local operation terminal 12 and the remote operation terminals 20.

The control device 30 accepts simultaneous logins from the local operation terminal 12 and the remote operation terminals 20 from a plurality of users and opens a plurality of communication ports to display different apparatus screens or different chat screens on the logged-in local operation terminal 12 and remote operation terminals 20.

The screen management unit 40 manages the screens displayed on the logged-in local operation terminal 12 and remote operation terminals 20. The screen management unit 40 is configured to include a login state management unit 50, an apparatus screen display state management unit 52, a communication unit 54, a screen data creation unit 56, an operation information determination unit 58, and an execution instruction unit 60.

The login state management unit 50 manages information (login state) about the logged-in local operation terminal 12 and remote operation terminals 20. The apparatus screen display state management unit 52 manages information (apparatus screen display state) about the apparatus screen displayed by the logged-in local operation terminal 12 and remote operation terminals 20.

The communication unit 54 controls a function of posting and browsing messages based on the user's operation on the chat screen displayed on the local operation terminal 12 and one or more remote operation terminals 20 logged into the same semiconductor manufacturing apparatus 10. In the semiconductor manufacturing system 1 of this embodiment, smooth and reliable communication between users of the local operation terminal 12 and one or more remote operation terminals 20 logged into the same semiconductor manufacturing apparatus 10 is implemented by the function of posting and browsing messages.

The screen data creation unit 56 creates screen data according to the users' operations on a screen data acquisition request, a login state, an apparatus screen display state, and a chat screen that are received from the logged-in local operation terminal 12 and remote operation terminals 20. On the apparatus screen where screen data is created by the screen data creation unit 56, a plurality of screens is present depending on the types of information to be displayed. The screen data creation unit 56 creates screen data in accordance with the screen data acquisition request received from the logged-in local operation terminal 12 and remote operation terminals 20.

On the chat screen on which screen data is created by the screen data creation unit 56, there is a screen with a plurality of (e.g., three) threads for posting and browsing messages by users operating the local operation terminal 12 and the one or more remote operation terminals 20 logged into the same semiconductor manufacturing apparatus 10. The thread is a collection of posting on one topic or agenda.

The operation information determination unit 58 determines whether execution instructions to the semiconductor manufacturing apparatus 10 according to the operation information are possible, based on the operation information received from the logged-in local operation terminal 12 and one or more remote operation terminals 20. In the semiconductor manufacturing system 1 of the embodiment, since the local operation terminal 12 and the one or more remote operation terminals 20 that are logged into the same semiconductor manufacturing apparatus 10 simultaneously display independent apparatus screens, the operation information determination unit 58 performs necessary determinations including determining whether or not execution instructions according to the operation information are possible. When execution instructions to the semiconductor manufacturing apparatus 10 according to the operation information are possible, the execution instruction unit 60 performs execution instructions according to the operation information.

The machine control unit 42 controls an operation and settings of each part of the semiconductor manufacturing apparatus 10 based on a request or execution instruction from the screen management unit 40. The input/output unit 44 transmits control instructions sent from the machine control unit 42 to each part of the corresponding semiconductor manufacturing apparatus 10 and receives necessary information from each part of the corresponding semiconductor manufacturing apparatus 10. Information received by the input/output unit 44 includes sensor output data. The machine control unit 42 transmits the information received by the input/output unit 44 from each part of the semiconductor manufacturing apparatus 10 to the screen management unit 40. For example, the screen management unit 40 uses information received from each part of the semiconductor manufacturing apparatus 10 to create screen data of the apparatus screen.

### <Chat Image>

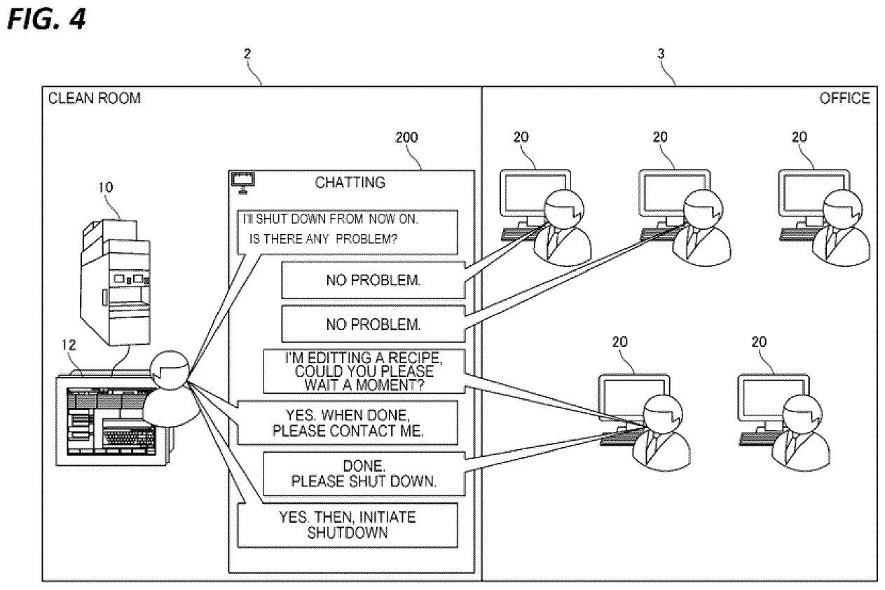

FIG. 4 is an image diagram of an example of posting and browsing messages according to the embodiment. The local operation terminal 12 in the clean room 2 illustrated in FIG. 4 and a plurality of (e.g., five) remote operation terminals 20 in the office 3 are logged into the same semiconductor manufacturing apparatus 10.

The local operation terminal 12 and the remote operation terminals 20 logged into the same semiconductor manufacturing apparatus 10 displays a chat screen 200 that enables posting and browsing messages between users operating the local operation terminal 12 and remote operation terminal 20 logged into the same semiconductor manufacturing apparatus 10.

For example, in the chat screen 200 in FIG. 4, a user operating the local operation terminal 12 posts “I will shut down from now on. Is there any problem?” before performing a shutdown operation of the semiconductor manufacturing apparatus 10.

The shutdown operation of the semiconductor manufacturing apparatus 10 is an example of an operation of making a user performing work on the semiconductor manufacturing apparatus 10 from the remote operation terminal 20 in the office 3 unable to work. The user performing work on the semiconductor manufacturing apparatus 10 from the remote operation terminal 20 in the office 3 may not use the apparatus screen due to the shutdown operation of the semiconductor manufacturing apparatus 10.

For this reason, a user operating the local operation terminal 12 may, before performing the shutdown operation of the semiconductor manufacturing apparatus 10, post “I will shut down from now on, is there any problem?” on the chat screen 200, read a reply from a user operating the remote operation terminal 20 logged into the same semiconductor manufacturing apparatus 10, and then, perform the shutdown operation of the semiconductor manufacturing apparatus 10.

Thus, in the semiconductor manufacturing system 1 according to the embodiment, smooth and reliable communication between users operating the local operation terminal 12 and the remote operation terminals 20 logged into the same semiconductor manufacturing apparatus 10 are possible, as illustrated, for example, in FIG. 4.

### <Screen>

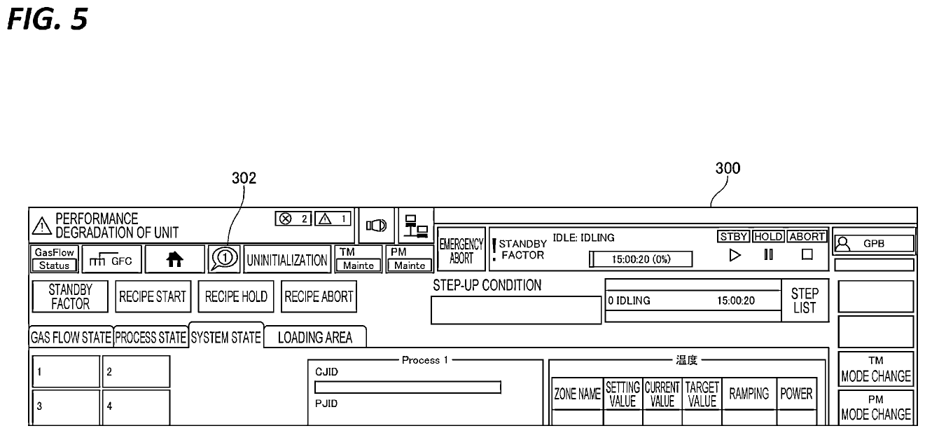

FIG. 5 is an image diagram of an example of an apparatus screen 300 displayed on the local operation terminal 12 logged into the semiconductor manufacturing apparatus 10. The image diagram illustrated in FIG. 5 illustrates a portion of the apparatus screen 300 on which a chat screen button 302 is displayed. The apparatus screen 300 may display a gas flow state, a process state, and a system state of the semiconductor manufacturing apparatus 10 into which the apparatus screen 300 is logged.

The apparatus screen 300 in FIG. 5 receives an operation to press the chat screen button 302 for the display of the chat screen from the user. The chat screen button 302 in FIG. 5 may display information such as the number of new messages (e.g., the number displayed in a speech bubble on the chat screen button 302 in FIG. 5).

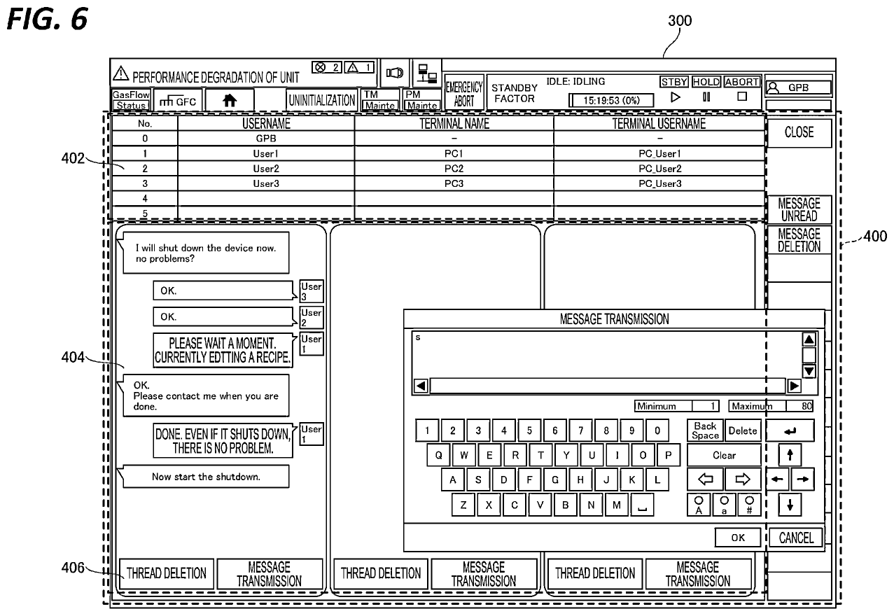

When the user of the local operation terminal 12 performs an operation of pressing the chat screen button 302 in FIG. 5, a chat screen 400 of FIG. 6 is displayed on the apparatus screen 300. On the chat screen 400, a list 402 of users operating the local operation terminal 12 and remote operation terminals 20 logged into the same semiconductor manufacturing apparatus 10 is displayed. Thus, the user of the local operation terminal 12 may operate the remote operation terminal 20 to identify other users logged into the same semiconductor manufacturing apparatus 10.

In addition, a thread 404 for posting and browsing messages is displayed on the chat screen 400 of FIG. 6. The chat screen 400 of FIG. 6 illustrates an example with three threads 404. In the chat screen 400 of FIG. 6, for example, the thread 404 may be created for each topic or agenda. A terminated thread may be deleted by pressing a thread deletion button 406.

For example, in the case of input using a touch panel without using an input device such as a mouse, scrolling of the thread 404 and searching for messages may not be facilitated. In the chat screen 400 according to this embodiment, smooth communication between users may be realized by, for example, switching the thread 404 for each topic or agenda.

FIG. 6 illustrates an example of posting English messages from the local operation terminal 12, but a Japanese message may also be posted. In addition, the thread 404 may be switched by a tab and displayed.

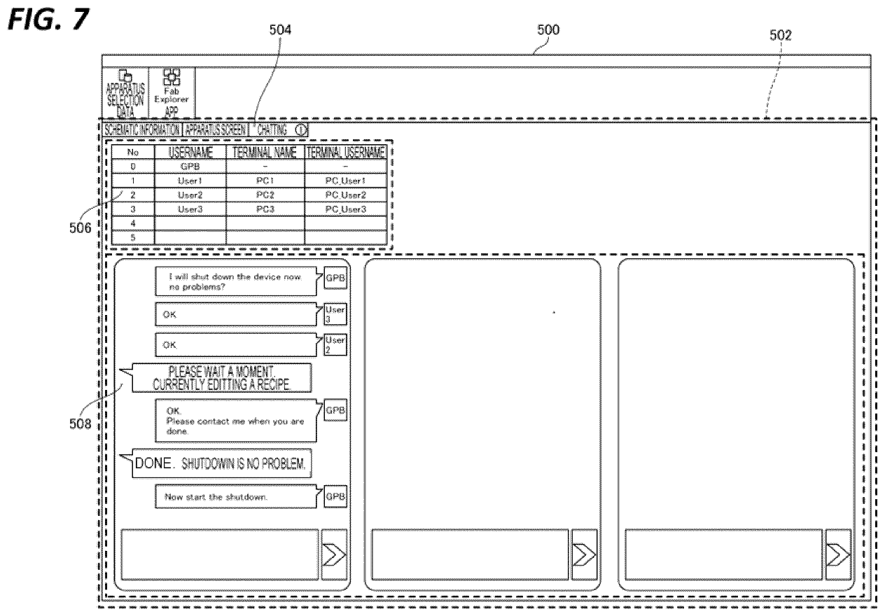

FIG. 7 is an image diagram of an example of a screen 500 displayed on the remote operation terminal 20 logged into the semiconductor manufacturing apparatus 10. The image diagram illustrated in FIG. 7 illustrates an example of the screen 500 on which a chat screen 502 is displayed. The chat screen 502 may display switching to the apparatus screen by a tab 504. The tab 504 in FIG. 7 may display information such as the number of new messages (e.g., the number displayed on the tab 504 in FIG. 7).

When the user of the remote operation terminal 20 performs an operation of pressing the tab 504 in FIG. 7, the chat screen 502 in FIG. 7 is displayed on the screen 500. On the chat screen 502, a list 506 of users operating the local operation terminal 12 and the remote operation terminals 20 that are logged into the same semiconductor manufacturing apparatus 10 is displayed. Thus, the user of the remote operation terminal 20 may operate the local operation terminal 12 and other remote operation terminals 20 to identify other users logged into the same semiconductor manufacturing apparatus 10.

On the chat screen 502 in FIG. 7, a thread 508 for posting and browsing messages is displayed. The chat screen 502 in FIG. 7 illustrates an example with three threads 508. In the chat screen 502 in FIG. 7, for example, the thread 508 may be created for each topic or agenda. A terminated thread may be deleted by an operation. In the chat screen 502 according to this embodiment, smooth and reliable communication between users may be realized by, for example, switching the thread 508 for each topic or agenda.

The control device 30 according to the embodiment may have a function of encouraging communication with other users by a chat function when users operating the local operation terminal 12 and the remote operation terminal 20 perform control of the semiconductor manufacturing apparatus 10 that affects work of other users. For example, when receiving a shutdown operation of the semiconductor manufacturing apparatus 10 from the local operation terminal 12 within the clean room 2, the control device 30 may perform a display operation to encourage notification by a chat function to a user operating the remote operation terminal 20 outside the clean room 2.

According to the semiconductor manufacturing system 1 according to this embodiment, it is possible for multiple people to smoothly work on the same semiconductor manufacturing apparatus 10 by a function of encouraging communication with other users by a chat function.

### <Conclusion>

According to the semiconductor manufacturing system 1 of this embodiment, it is possible to provide a technology that realizes smooth and reliable communication between users operating the local operation terminal 12 and the one or more remote operation terminals 20 that are logged into the same semiconductor manufacturing apparatus 10.

According to the present disclosure, it is possible to provide a technology that implements smooth and reliable communication between users operating a local operation terminal and a remote operation terminal that are logged into the same semiconductor manufacturing apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A control device for controlling a semiconductor manufacturing apparatus including a local operation terminal displaying an apparatus screen of the semiconductor manufacturing apparatus and one or more remote operation terminals displaying the apparatus screen, the control device comprising:
a login state management circuitry configured to manage the local operation terminal and at least one of the remote operation terminals that are logged into the same semiconductor manufacturing apparatus; and
a communication circuitry configured to provide a function of posting and browsing a message between a first user operating the local operation terminal and a second user operating the at least one of the remote operation terminals that are logged into the same semiconductor manufacturing apparatus, by transmitting screen data enabling the posting and browsing of the message to the local operation terminal and the at least one of the remote operation terminals that are logged into the same semiconductor manufacturing apparatus.

2. The control device according to claim 1, wherein the local operation terminal is within a clean room in which the semiconductor manufacturing apparatus is installed, and the remote operation terminal is outside the clean room.

3. The control device according to claim 1, wherein the communication circuitry provides the function of posting and browsing of the message by a plurality of threads.

4. The control device according to claim 3, wherein the communication circuitry receives an operation to delete the threads from a first user operating the local operation terminal or a second user operating the at least one of the remote operation terminals, where the first and second users are logged into the same semiconductor manufacturing apparatus.

5. The control device according to claim 1, wherein the communication circuitry suggests, to the first user operating the local operating terminal, the posting of the message to the second user operating the remote operating terminal, according to a type of an operation received from the first user operating the local operating terminal.

6. A control method comprising:
providing a control device for controlling a semiconductor manufacturing apparatus based on an operation received from users by a local operation terminal displaying an apparatus screen of the semiconductor manufacturing apparatus and one or more remote operation terminals displaying the apparatus screen;
managing the local operation terminal and at least one of the remote operation terminals that are logged into the same semiconductor manufacturing apparatus; and
providing a function of posting and browsing a message between a first user operating the local operation terminal and a second user operating the at least one of the remote operation terminals that are logged into the same semiconductor manufacturing apparatus, by transmitting screen data enabling the posting and browsing of the message to the local operation terminal and at least one of the remote operation terminals that are logged into the same semiconductor manufacturing apparatus.

7. A semiconductor manufacturing system comprising:
a local operation terminal configured to display an apparatus screen of a semiconductor manufacturing apparatus;
one or more remote operation terminals connected to the semiconductor manufacturing apparatus through a network and configured to display the apparatus screen; and
a control device configured to control the semiconductor manufacturing apparatus based on an operation received from a first user operating the local operation terminal and a second user operating the remote operation terminal, each of the local operation terminal and the at least one of the remote operation terminals displaying the apparatus screen,
wherein the control device includes,
a login state management circuitry configured to manage the local operation terminal and the at least one of the remote operation terminals that are logged into the same semiconductor manufacturing apparatus; and
a communication circuitry configured to provide a function of posting and browsing a messages between the first user operating the local operation terminal and the second user operating the at least one of the remote operation terminals that are logged into the same semiconductor manufacturing apparatus, by transmitting screen data enabling posting and browsing of the message to the local operation terminal and the remote operation terminal that are logged into the same semiconductor manufacturing apparatus.
